(19) United States
(12) Patent Application Publication
(10) Pub. No.: US 2007/0172989 A1
(43) Pub. Date: Jul. 26, 2007

(54) Polymerization initiator systems containing aluminum compounds as curing inhibitors and polymerizable compositions made therewith

(75) Inventor: Glen Rosini, Seabrook, TX (US)

Correspondence Address: Louis A Morris;Akzo Nobel Inc, Intellectual Property Dept, 7 Livingstone Avenue, Dobbs Ferry, NY, 10522, US

(73) Assignee: AKZO NOBEL N.V., Armhem (NL)

(21) Appl. No.: 10/587,872

(22) PCT Filed: Feb. 23, 2005
(86) PCT No.: PCT/EP05/01991

§ 371 Date: Aug. 30, 2006

Related U.S. Application Data
(60) Provisional application No. 60/548,828, filed on Feb. 27, 2004.
(60) Provisional application No. 60/548,989, filed on Mar. 1, 2004.

(51) Int. Cl. H01L 21/00

(52) U.S. Cl. 438/117

(57) ABSTRACT

The invention is directed to a composition comprising an organoborane/amine complex and an effective amount of an aluminum compound to inhibit curing of the organoborane/amine complex when used as part of a polymerization initiator system in a polymerizable composition containing one or more monomers, oligomers or polymers having olefinic unsaturation. The compositions of the invention can be used in polymerizable compositions, adhesive compositions and coatings compositions containing compounds having moieties which polymerize under free radical polymerization conditions.

This application claims priority from U.S. patent application Ser. Nos. 60/548,828 and 60/548,987, filed Feb. 27, 2004 and Mar. 1, 2004, respectively.

### BACKGROUND OF THE INVENTION

The present invention relates to a novel curing inhibitor for amine organoborane complex polymerization initiators of the type described and claimed in U.S. Patent Application Publication No. 2002/0058764, the references described therein to Mottus et al., Skoultchi, Zharov et al., and Pocius, in the following related U.S. Patent Application Publication Nos. 2002/0025381, 2002/0028894, 2002/0031607, 2002/0033227, and 2003/0120005, and in the original U.S. patent application Ser. No. 09/466,321. All of these patent applications and patents are incorporated herein by reference as covering the amine organoborane complex polymerization initiators that are useful in the practice of the present invention.

As stated in U.S. Patent Application Publication No. 2002/0058764, it is desirable to have polymerizable compositions and adhesive compositions which can cure on demand (polymerization can be initiated when desired). A significant problem with cure on demand compositions is the stability of the compositions, which can result in an increased viscosity causing difficulties in handling and reduced functionality of the polymerizable composition or adhesive composition. Many of the complexes disclosed in the prior art are not stable in compositions containing olefinic unsaturation at, or near, ambient temperatures. This instability can result in polymerization before desired and can result in compositions which are unsuitable for the desired use.

Therefore, there is a need for initiator systems for free radical polymerization which are safe to handle, not pyrophoric, which can be used to form cure on demand polymer systems or can be used in adhesive systems which cure on demand. What are further needed are initiator systems that have enhanced stability in the presence of compounds having olefinic unsaturation, thus improving the ability to cure on demand. What are further needed are polymerizable compositions and adhesive systems which are thermally stable at, or near, ambient temperatures and which will undergo polymerization when the user desires.

### SUMMARY OF THE INVENTION

One embodiment of the present invention is a composition comprising an organoborane/amine complex and an effective amount of an aluminum compound to inhibit curing of the organoborane/amine complex when used as part of a polymerization initiator system in a polymerizable composition containing one or more monomers, oligomers or polymers having olefinic unsaturation. Paragraph 0010 of U.S. Patent Application Publication No. 2002/0058764 provides a non-limiting but representative description of organoborane and amine components that can be selected for use, and the aluminum compound is selected from the group of organoaluminum compounds of the formula Al₂R₆, wherein R is either C₁-C₁₂ alkyl or C₁-C₁₂ alkoxy, with each of the six R groups being the same or different.

In another embodiment the invention comprises a polymerizable composition which comprises an organoborane/amine complex, an effective amount of an aluminum compound and one or more of monomers, oligomers or polymers having olefinic unsaturation which are capable of polymerization by free radical polymerization. Additional background pertaining to polymerizable compositions, their mode of use and their applications are disclosed in paragraphs 0011 and 0012 of this same patent publication and are relevant to the compositions of this invention.

The complexes of the invention are safe to handle, not pyrophoric, are stable at, or near, ambient temperature and therefore will not initiate polymerization at, or near, ambient temperature in the absence of an initiator that causes the complex to disassociate. The polymeric compositions of the invention are stable at, or near, ambient temperature and can be cured upon demand by causing the complex to disassociate.

### DESCRIPTION OF PREFERRED EMBODIMENTS

As described in paragraph 0014 and the first seven lines of paragraph 0015 of U.S. Patent Application Publication No. 2002/0058764, the organoborane used in the composition is a trialkyl borane or an alkyl cycloalkyl borane. Preferably such borane corresponds to Formula 1:
B(R²)3 Formula 1

wherein B represents Boron; and R² is separately in each occurrence a C₁₋₁₀ alkyl, C₃₋₁₀ cycloalkyl, or two or more of R² may combine to form a cycloaliphatic ring. Among preferred organoboranes are tri-ethyl borane, tri-isopropyl borane and tri-n-butylborane.

A variety of amines can be used as complexing agents to form the organoborane/amine initiator complex. U.S. Patent Application Publication No. 2002/0058764 discloses a broad range of useful amine components that can be selected for use (paragraphs 0017 to 0044, incorporated herein by reference). U.S. Pat. No. 5,935,711 also discloses useful amine components (column 5, line 61 to column 7, line 61, incorporated herein by reference). These patents provide a non-limiting but representative description of amine components that can be selected for use.

A variety of organoaluminum compounds of the formula Al₂R₆ can be selected for use in the present invention. In the preceding formula, R is either C₁-C₁₂ alkyl or C₁-C₁₂ alkoxy, with each of the six R groups being the same or different. By extension, this formula also represents compounds explicitly designated as AlR₃ and Al(R)(R′₂) for compounds of the formula with even numbers of alkyl and/or alkoxy groups. The R groups can be a mixture of about three alkyl groups and about three alkoxy groups. The terms “alkyl” and “alkoxy” as used herein includes both straight-chain and branched-chain groups.

Non-limiting examples of organoaluminum compounds within the scope of this invention include trimethylaluminum, triethylaluminum, tri-n-propylaluminum, tri-n-butylaluminum, triisobutylaluminum, tri-n-hexylaluminum, tri-n-octylaluminum, aluminum triethoxide, aluminum isopropoxide, aluminum tri-s-butoxide, aluminum tri-t-butoxide, diethylaluminum ethoxide, diisobutylaluminum ethoxide, triethyl(tri-s-butoxy)dialuminum, tri-n-butyl(triisopropoxy)dialuminum, and mixtures thereof.

The organoaluminum compound can be added as a component during any stage of the preparation of the polymerizable composition. Preferably the organoaluminum compound is added directly to the preformed organoborane/amine complex, and most preferably the organoaluminum compound is added directly to the organoborane prior to addition of the amine.

The molar ratio of boron to aluminum in the composition is relatively important. If the molar ratio of boron to aluminum is too high, then the polymerizable composition made therewith may experience an undesirable increase in viscosity. If the molar ratio of boron to aluminum is too low, the composition may be pyrophoric (the absolute ratio at which the composition is pyrophoric is dependent upon the organoaluminum compound that is used) or, for adhesive uses, there may be problems with adhesion. The molar ratio of boron to aluminum is from about 1.0:1.0 to about 50.0:1.0. Preferably, the molar ratio of boron to aluminum is from about 10.0:1.0 to about 30.0:1.0.

Similarly, the molar ratio of amine compound to borane compound in the complex is relatively important. Preferably, the molar ratio of amine compound to organoborane compound is from about 3.0:1.0 to about 1.0:1.0, even more preferably from about 2.0:1.0 to about 1.0:1.0, as disclosed in U.S. Patent Application Publication No. 2002/0058764 (paragraph 45, incorporated herein by reference).

The composition of the invention comprising an organoborane/amine complex and an effective amount of an aluminum compound may be readily prepared using known techniques. The aluminum compound may be added at any time during the preparation of either the organoborane/amine complex or the polymerizable composition. The order of addition of the amine and the organoborane (or organoborane/aluminum compound mixture) to form the organoborane/amine complex is not important for most amine/organoborane combinations. Typically, the components are combined in an inert atmosphere with slow stirring. An exotherm is often observed and cooling of the mixture is, therefore, recommended. If the ingredients have a high vapor pressure, it is desirable to keep the reaction temperature below about 70° C. to 80° C. Once the materials are well mixed, the complex is permitted to cool to room temperature. No special storage conditions are required, although it is preferred that the complex be kept in a capped vessel under an inert atmosphere, in a cool, dark location.

The complexes and compositions of the invention are air stable. By “air stable” it is meant that when the complexes are stored in a capped vessel at room temperature (about 20° C. to 22° C.) and under otherwise ambient conditions (i.e., not under a vacuum and not in an inert atmosphere), the complexes remain useful as polymerization initiators for at least about two weeks, although the complexes may be readily stored under these conditions for many months. By “air stable” it is also meant that the complexes are not pyrophoric.

Polymerizable compounds which may be used in the polymerization compositions of the invention include any monomers, oligomers, polymers or mixtures thereof which contain olefinic unsaturation which can polymerize by free radical polymerization. U.S. Patent Application Publication No. 2002/0058764 (paragraphs 46 to 48, and references therein, incorporated herein by reference) provides a non-limiting but representative description of polymerizable compounds and compositions relevant to the invention. Furthermore, the same patent application (paragraphs 0052 to 0071 and paragraphs 0073 to 0075, incorporated herein by reference) discloses further details regarding the use of and applications for said polymerizable compositions.

The part of the adhesive or polymerizable compositions of the invention which contains the amine-organoborane complex containing an effective amount of aluminum compound preferably displays thermal stability at, or above, room temperature. Thermal stability as used herein means the amine-organoborane complex does not disassociate and initiate polymerization of the olefinic unsaturated compounds present in the composition. Thermal stability can be measured by determining the temperature at which the viscosity of the composition begins to increase. Preferably, the temperature at which the viscosity of the composition increases is greater than about 40° C., more preferably greater than about 60° C. and most preferably greater than about 80° C. The increase in viscosity indicates that the amine-organoborane complex is disassociated and polymerization has been initiated.

### EXAMPLES

The following examples are included for illustrative purposes only and are not intended to limit the scope of the claims. Unless otherwise stated, all parts and percentages are by weight.

Preparation of the Organoborane/Amine Complex

394 cc of tri-n-butyl borane (TNBB) was added to a nitrogen purged flask equipped with an agitator. In an example of the use of an aluminum compound, the aluminum compound is added to make a molar ratio of boron to aluminum of between 10:1 to 30:1. As such, in one example, 21 cc of tri-n-butyl aluminum (TNBAL, 18.5:1 molar ratio of boron to aluminum) was slowly added to the stirred organoborane solution, maintaining the temperature below 55° C. Alternately, the aluminum compound could be added after the addition of amine. A weighed amount of amine is placed in a closed feed vessel and purged with nitrogen. The amine is then added to the organoborane solution (either with or without the presence of the aluminum compound of the invention) to make a molar ratio of organoborane to amine of between 1:1 to 1:3. As such, in the current example, 242 cc of 3-methoxypropyl amine (MOPA, 1:1.47 molar ratio of boron to nitrogen) was added in small portions to the stirred TNBB/TNBAL solution, maintaining the temperature below 55° C. The solution was then stirred for about 30 minutes. Several complexes were prepared and tested in the composition as described herein. Table 1 contains the compositional data of the complexes and the results of the testing.

Preparation of Polymerizable Compositions

The compositions tested contained 15 parts by weight of the organoborane/amine complex (with or without aluminum containing dopant) mixed with 70 parts by weight of an acrylic resin (comprised of 79% methylmethacrylate, MMA, and 21% of polymethylmethacrylate, PMMA, of 270 K Mw), 8 parts by weight of a polyoxyalkyleneamine (Jeffamine T403), 7 parts by weight of a Core-shell impact modifier (Paraloid EXL2691A) and 0.03% by weight of an antioxidant (2,6-ditertbutyl-4-methyl phenol, BHT). The compositions containing triethylborane (TEB) did not contain BHT. After the batches were properly mixed, they were placed in 8 oz. jars. The initial viscosity was measured with a Brookfield Digital Viscometer HATDV II, spindle #7 at 20 rpm.

Thermal Stability Testing

U.S. Patent Application Publication No. 2002/0058764 (paragraphs 84 and 85, incorporated herein by reference) discloses several methods for testing the thermal stability of the adhesive or polymerizable compositions of the invention. In the method used herein, the time it takes for the viscosity to reach 100 kcPs at 40° C. was determined by periodic measurement of the viscosity of a polymerizable composition.

Jars of polymerizable compositions were prepared as above, and were then placed in an oven set at 40° C., for the number of days indicated in the data (the compositions containing TEB were held at 55° C. due to greater sample stability). On the day that the viscosity was measured the samples were taken out of the oven and allowed to cool to room temperature, usually 4-6 hours. After the viscosity was measured, the samples were placed back in the oven. This procedure was repeated until the samples gelled , and examination of the data revealed the number of days under 100 kcPs. The results of the testing are summarized in Table 1.

TABLE 1

| | | | | Al | | | | |
|---|---|---|---|---|---|---|---|---|
| | | | | added | Molar | Molar | | Days |
| | | | | before | N:B | B:Al | | Under |
| Example | Borane | Amine | Al Source | amine | Ratio | Ratio | Pyrophoric | 100 kcPs |
| 1 | TNBB | MOPA | None | — | 1.31 | — | No | 2.2 |
| 2 | TNBB | MOPA | ⁿBu₃Al₂(OiPr)₃ | Y | 1.32 | 83.5 | No | 8.6 |
| 3 | TNBB | MOPA | ⁿBu₃Al₂(OiPr)₃ | Y | 1.34 | 41.2 | No | 16.5 |
| 4 | TNBB | MOPA | ⁿBu₃Al₂(OiPr)₃ | Y | 1.38 | 20.1 | No | >19 |
| 5 | TNBB | MOPA | ⁿBu₃Al₂(OiPr)₃ | N | 1.38 | 20.1 | No | 15.4 |
| 6 | TNBB | MOPA | ⁿBu₃Al₂(OiPr)₃ | N | 1.47 | 8.8 | No | 19.4 |
| 7 | TNBB | MOPA | ⁿBu₃Al₂(OiPr)₃ | N | 1.68 | 3.8 | No | 24 |
| 8 | TNBB | MOPA | TNBAL | Y | 1.34 | 41.2 | No | 9.9 |
| 9 | TNBB | MOPA | TNBAL | N | 1.38 | 20.1 | No | 13.6 |
| 10 | TNBB | MOPA | Al(OiPr)₃ | N | 1.38 | 20.0 | No | 8.7 |
| 11 | TEB | MOPA | None | — | 1.46 | — | No | 3.8 |
| 12 | TEB | MOPA | ⁿBu₃Al₂(OiPr)₃ | Y | 1.54 | 37.3 | No | 4.5 |

The following abbreviations are used in TABLE 1.
TNBB is tri-n-butylborane
TEB is triethylborane
MOPA is 3-methoxypropylamine
IPDA is isophorone diamine
TNBAL is tri-n-butylaluminum

1. A composition comprising an organoborane/amine complex and an effective amount of at least one organoaluminum compound to inhibit curing of the organoborane/amine complex when used as part of a polymerization initiator system containing olefinic unsaturation.

2. A composition as claimed in claim 1 wherein the organoaluminum compound is of the formula Al₂R₆, with R being selected from the group consisting of C₁-C₁₂ alkyl and C₁-C₁₂ alkoxy and with each of the six R groups being the same or different.

3. A composition as claimed in claim 1 having a molar ratio of boron to aluminum of from about 1.0:1.0 to about 50.0:1.0.

4. A composition as claimed in claim 1 having a molar ratio of boron to aluminum of from about 10.0:1.0 to about 30.0:1.0.

5. A composition as claimed in claim 1 wherein the organoaluminum compound is one or more of trimethylaluminum, triethylaluminum, tri-n-propylaluminum, tri-n-butylaluminum, triisobutylaluminum, tri-n-hexylaluminum, tri-n-octylaluminum, aluminum triethoxide, aluminum isopropoxide, aluminum tri-s-butoxide, aluminum tri-t-butoxide, diethylaluminum ethoxide, diisobutylaluminum ethoxide, triethyl(tri-s-butoxy)dialuminum, tri-n-butyl(triisopropoxy)dialuminum.

6. A composition as claimed in claim 1 wherein the organoaluminum compound was added to an organoborane prior to reaction with amine in preparing the organoborane/amine complex.

7. A composition as claimed in claim 1 wherein the organoaluminum compound was added to a preprepared organoborane/amine complex.

8. A polymerizable composition comprising one or more monomers, oligomers or polymers having olefinic unsaturation and, as the initiator system, the composition of claim 1.
